(19) United States
(12) Patent Application Publication
(10) Pub. No.: US 2026/0331857 A1
(43) Pub. Date: Oct. 22, 2026

(54) AN OPTICAL CIRCUIT ARRANGEMENT

(71) Applicant: Cambridge Raman Imaging Limited, Cambridge, Cambridgeshire (GB)

(72) Inventors: Francesco Crisafi, Milano (IT); Gabriele Di Noia, Milano (IT); Matteo Negro, Milano (IT)

(73) Assignee: Cambridge Raman Imaging Limited, Cambridge, Cambridgeshire (GB)

(21) Appl. No.: 19/100,484

(22) PCT Filed: Aug. 3, 2023
(86) PCT No.: PCT/GB2023/052061

§ 371 Date: Jan. 31, 2025

(30) Foreign Application Priority Data
Aug. 3, 2022 (GB) 2211289.0

(51) Int. Cl. H01S 3/067; H01S 3/08; H01S 3/1115; H01S 3/16

(52) U.S. Cl. CPC H01S 3/06791; H01S 3/06716; H01S 3/08013; H01S 3/1115; H01S 3/1608; H01S 3/1616; H01S 3/1618

(57) ABSTRACT

An optical circuit (100) for a laser device, the optical circuit (100 ) comprising: a first polarization-maintaining optical cavity (110a) comprising: a first gain medium (140a) excitable by a first pump light source (130a) to generate light at a first range of wavelengths; and a first saturable absorber 170a configured to carry out passive mode locking of the light pulses in the first polarization-maintaining optical cavity (110a); and a second polarization-maintaining optical cavity (110b) comprising: a second gain medium (140b) different to the first gain medium (140a) excitable by a second pump light source (130b) to generate light at a second range of wavelengths; and a second saturable absorber (170b) configured to carry out passive mode locking of the light pulses in the second polarization-maintaining optical cavity (110b), wherein the first polarization-maintaining optical cavity (110a) and the second polarization-maintaining optical cavity (110b) share a common branch (120), and wherein the common branch (120) does not include a saturable absorber.

### FIELD OF INVENTION

The present invention relates to optical circuit arrangements and, in particular, optical circuit arrangements for use in a coherent Raman micro-spectroscopy laser device.

### BACKGROUND

Raman spectroscopy enables label-free chemical signatures of tissues and cells. It is based on the Raman scattering effect of molecules with the use of a single continuous wave laser. Such spontaneous Raman scattering is weak, and therefore Raman spectroscopy is typically slow. Coherent Raman spectroscopy (CRS), including coherent anti-Stokes Raman scattering (CARS), and stimulated Raman scattering (SRS) relies on nonlinear excitation of molecules, and can enhance the Raman intensity by orders of magnitude. In theory, such increase in Raman intensity allows measurement to be made at video-rate imaging speeds, which, in theory, means that CRS could be used in many applications in many different fields.

CRS can be implemented in a narrowband or in a broadband fashion, where narrowband means that a single vibrational frequency is excited at a time and broadband means that multiple vibrational modes are excited simultaneously. The narrowband approach is typically named “hyperspectral CRS” and it is based on narrowband tunable laser sources which permit to reconstruct the vibrational spectrum by serially acquiring the response of the system at different Raman modes. The broadband approach is generally defined as “multiplex CRS” and it relies on the combination of a broadband optical pulse and a narrowband one, thus leading to the parallelization of the Raman modes that can be excited and detected simultaneously. Multiplex CRS has the great advantage of single-shot spectral acquisition, which enables fast and chemically-selective imaging at once. Multiplex SRS imaging is a particularly beneficial technique due to the absence of the non-resonant background.

CRS requires the use of synchronised ultra-fast at least pico-second lasers from two laser sources, where pump and Stokes pulses matching the Raman frequency and bandwidths are used for setting up and detecting a vibrational coherence within a sample. Currently, solid-state lasers pumping optical parametric oscillators have been widely used as the laser source for CRS, as these laser sources allow access to the full Raman spectrum (0-4000 cm⁻¹). Such solid-state laser devices comprise a bulk piece of doped crystal or glass as the gain medium and require the use of bulky optics. They are, therefore, not only susceptible to misalignment and prone to instability, but their use also incurs a high capital cost. Furthermore, their relatively large footprints prevent them from being deployed effectively in clinical environments, for example, they cannot be easily moved around different wards in a hospital, nor they can be handled conveniently.

The use of fiber-format lasers has gained popularity in recent years because such laser devices offer a simpler, more cost effective excitation source with a smaller footprint. They are also more reliable and do not require alignment, in comparison with the solid-state lasers pumping optical parametric oscillators.

U.S. Pat. No. 7,372,880 discloses a pulsed fibre laser that is capable of generating ultrashort light pulses. The pulsed fibre laser comprises an optical ring resonator having a length of rare-earth doped fiber as a gain medium. In use, the gain medium responds to a pumped light source to produce optical gain in the resonator. To facilitate pulse generation, carbon nanotubes (CNT) are employed as a non-linear optical or saturable absorber material to convert continuous wave laser into ultrafast optical pulse trains. A saturable absorber is an optical component with a certain optical loss, which is reduced at high optical intensities. Each time a pulse hits a saturable absorber as it circulates the optical ring resonator, it saturates the saturable absorber's absorption, thus temporarily reducing the losses. In each resonator round trip, the saturable absorber will then favor the light which has somewhat higher intensities, because this light can saturate the absorption slightly more than light with lower intensities. After many round trips, a single pulse will remain.

There are studies in the field directed towards the synchronization of dual-wavelength ultrafast laser sources with a passive mode-locking technique, in order to produce synchronized light pulses from two different laser sources. This technique requires the use of a common saturable absorber shared by the two laser sources, for example optically coupling the common saturable absorber to two fiber cavities doped with different rare-earth materials.

Zhang et al., “Passive synchronization of all-fiber lasers through a common saturable absorber”, Optics Letter, (2011) (Zhang) discloses the synchronization of two all-fiber mode-locked lasers, operating at 1 μm and 1.54 μm, coupled through the use of a shared single-wall carbon nanotube absorber. Furthermore, Zhang et al., “Ultrafast fibre laser sources: Example of recent developments”, Optical Fiber Technology, (2014) summarizes the recent developments in the field of ultrafast compact all-fiber lasers. More specifically, Zhang discloses the use of graphene and single-wall carbon nanotubes as passive elements to carry out synchronization and passive mode-locking of laser pulses in two coupled optical cavities. The optical cavities comprise an ytterbium or erbium doped fiber gain medium for generating dual-wavelength light pulses for pump probe spectroscopy.

Sotor et al., “Passive synchronization of erbium and thulium doped fiber mode-locked lasers enhanced by common graphene saturable absorber”, Optics Express (2014) (Sotor) discloses the use of a common graphene saturable absorber for synchronizing light pulses from two loop resonators, each comprises one of erbium and thulium doped fiber gain medium. In Sotor, a 1569 nm laser diode is used for exciting the thulium gain medium, in order to generate light pulses at 2 μm. A wavelength division multiplexer (WDM) filter is provided to filter out any unabsorbed pump light at the wavelength of 1569 nm, wherein said unabsorbed pump light is purged to the erbium loop resonator to be output with the 1.5 μm light pulses.

It would be desirable to provide more effective and robust dual-cavity passively synchronized optical circuits for use in laser devices.

### SUMMARY OF INVENTION

The invention in its various aspects is defined in the independent claims below to which reference should now be made. Optional features are set forth in the dependent claims.

In a first aspect, the present disclosure provides an optical circuit for a laser device, in particular, a laser device for use in CRS. The optical circuit comprising a first polarization-maintaining optical cavity and a second polarization-maintaining optical cavity. The first polarization-maintaining optical cavity comprising a first gain medium excitable by a first pump light source to generate light at a first range of wavelengths, and a first saturable absorber configured to carry out passive mode locking of the light pulses in the first polarization-maintaining optical cavity. The second polarization-maintaining optical cavity comprising a second gain medium different to the first gain medium excitable by a second pump light source to generate light at a second range of wavelengths, and a second saturable absorber configured to carry out passive mode locking of the light pulses in the second polarization-maintaining optical cavity. The first polarization-maintaining optical cavity and the second polarization-maintaining optical cavity share a common branch, wherein the common branch does not include a saturable absorber.

Saturable absorbers can be used to initiate and promote strong intra-cavity pulsing through intensity dependent loss, i.e. a pulse (probe) sees a loss reduction caused by a higher energy pulse (pump). Unlike shared saturable absorber laser cavity configurations, the disclosed common branch optical circuit arrangements utilize independent saturable absorbers in each optical cavity. As a result, the operating life of the disclosed optical circuit arrangements may be extended due to the reduced stresses on the saturable absorbers resulting from excessive non-linear saturable absorption/heating induced by simultaneous pulses from multiple optical cavities, as in the known shared saturable absorber laser cavity configurations. Additionally, the inventors of the present disclosure have found that the properties of a saturable absorber may differ depending on the number of wavelengths transmitted through it. This cross-talk effect is unpredictable and typically detrimental for the mode-locking and/or synching mechanism of each individual wavelength in the common branch shared by the two optical cavities. Therefore, the provision of two independent saturable absorbers, one for each optical cavity, may allow each saturable absorber to be optimized for the wavelength associated with its respective optical cavity and avoid undesirable cross-talk effects.

Like the shared saturable absorber laser cavity configurations, the disclosed common branch optical circuit arrangements utilize passive optical synchronization resulting from cross-phase modulation (XPM) interactions in the common branch. The strength of the XPM interaction in the common branch is proportional to the peak intensity of the interacting pulses and the non-linearity of the medium. The interaction length of the common branch influences the XPM-induced synchronization range. Generally, the longer the common branch, the better the XPM interaction, however, an upper limit is imposed on the permissible length of the common branch due to the group-velocity mismatch (GVM) phenomenon. It has been found that the disclosed optical circuits comprising a relatively short common branch may be as effective as a complete cavity injection with regards to passive synchronization. The disclosed common branch optical circuits may exhibit improved passive synchronization over cavity injection arrangements due to their slave-slave optical structure, in which the XPM induced repetition rate change feedback effects the pulses in both optical cavities, increasing the permissible cavity length mismatch in the optical circuit. Furthermore, performing the XPM in a common branch between two optical cavities ensures enough XPM interactions for synchronisation without the need for external amplification, leading to a more efficient optical circuit with a lower lasing threshold.

A lasing threshold is the lowest excitation level at which a laser's output is dominated by stimulated emission rather than by spontaneous emission. Below the threshold, the laser's output power rises slowly with increasing excitation. Above the lasing threshold, the slope of power vs excitation is orders of magnitude greater. The linewidth of the laser's emission also becomes orders of magnitude smaller above the lasing threshold. Above the lasing threshold, the laser is said to be lasing.

The configuration of the first and second optical cavities in the disclosed optical circuits may take on several different forms.

In a first embodiment, the first polarization-maintaining optical cavity may have a ring configuration and the second polarization-maintaining optical cavity may have a ring configuration. In a ring configuration, optical cavities follow a path which forms a complete/continuous optical loop. In a ring-ring configuration, a portion of the two optical cavities is joined by the common branch. Compared with linear cavity configurations, ring-ring cavity configurations experience lower losses per round trip of the optical cavities, when employing transmissive saturable absorbers (CNTs, Graphene, transmissive semiconductor based SA), since the pulses in each optical cavity only pass through a saturable absorber once. There are no restrictions on the possible location of the common branch within each of the optical cavities except between the pump WDM and the active fiber, since the presence of the common branch WDMs will block pump light from reaching the active fiber due the presence of optical filters.

In a second embodiment, the first polarization-maintaining optical cavity may have a linear configuration and the second polarization-maintaining optical cavity may have a ring configuration. In a linear configuration, optical cavities follow a linear path, the ends of which do not meet. Compared with a ring-ring configuration, a linear-ring configuration has the advantage of being more compact, since the total fiber length is half with respect to a ring cavity counterpart. Moreover, for dispersion compensated cavities which employ FBGs and SESAMs, the linear cavity arrangement is always less lossy with respect to the ring counterpart, leading to lower lasing thresholds.

In a third embodiment, the first polarization-maintaining optical cavity may have a linear configuration and the second polarization-maintaining optical cavity may have a linear configuration. Advantageously, a linear-linear optical cavity configuration effectively doubles the XPM interaction length, thereby increasing the acceptable cavity mismatch in the optical circuit. This arises since, in a linear-linear configuration, cavity pulses pass through the common branch twice per round trip of each cavity.

Optionally, the first saturable absorber is different from the second saturable absorber.

Optionally, at least one of the first saturable absorber or the second saturable absorber comprises at least one of a Graphene/carbon allotrope, single-walled carbon nanotube (SWCNT), semiconductor saturable absorber mirror (SESAM), or transmissive semiconductor based saturable absorber. Advantageously, these saturable absorber (SA) types may reduce the footprint of the optical cavity arrangement since they can provide effective mode-locking functions with shorter fiber lengths compared to non-linear amplifying loop mirror and non-linear polarization rotation/evolution SA types. This enables a greater proportion of fiber to be used in the common branch leading to a larger cavity mismatch tolerance.

Any of the SA types described may be used in any of the described cavity configurations. Transmissive SAs, such as Graphene/carbon allotrope, SWCNTs and transmissive semiconductor based SAs are particularly suited to a ring cavity, since the linear losses are experienced once per cavity round-trip, leading to a lower lasing threshold. Reflective SAs however, such as SESAMs, are particularly suited to a linear cavity. Where a transmissive SA is used in a linear cavity arrangement, a fiber coupled mirror must be provided on the output of the SA. Particularly advantageous SA combinations with reduced lasing thresholds include a first transmissive SA and a second transmissive SA for a ring-ring cavity configurations, a first transmissive SA and a second SESAM SA for ring-linear cavity configurations, and a first SESAM SA and a second SESAM SA for linear-linear cavity configurations.

Optionally, at least one of the first saturable absorber and/or the second saturable absorber is mounted on a temperature controlled system. This ensures that the first and/or second saturable absorber operates in a consistent and predictable manner.

Optionally, the common branch includes a high non-linearity device or material. The high non-linearity device may comprise one or more of a photonic crystal fiber (PCF), a highly non-linear fiber (HNLF), a small mode area fiber, or a tapered fiber. The high non-linearity material may comprise two-dimensional materials (TDMs), polyethylene terephthalate (PET), polymethyl methacrylate (PMMA), and/or cellulose acetate (CA). The non-linear index of a standard single-mode fiber at 1030 nm is around 2.7-2.8×10⁻⁷ cm²/GW. The materials listed above have a higher non-linear index or effective non-linear coefficient with respect to a standard fiber and thus higher non-linearity. The high non-linearity devices typically have the non-linear index the same as a standard fiber, but achieve higher non-linearity due to smaller mode areas. The high non-linearity device or the material may be spliced between two single mode polarization-maintaining fibers.

Optionally, the common branch comprises a single mode polarization-maintaining fiber.

Optionally, the common branch comprises a single mode fiber.

Optionally, at least one of the first polarization maintaining optical cavity or the second polarization-maintaining optical cavity comprises a polarizing isolator or dispersion compensating device or circulator with dispersion compensating device.

Optionally, at least one of the first gain medium or the second gain medium comprises a ytterbium, erbium, neodymium or thulium doped fiber.

Optionally, at least one of the first polarization maintaining optical cavity or the second polarization-maintaining optical cavity comprises a polarizing fiber coupler.

Optionally, at least one of the first polarization-maintaining optical cavity or the second polarization-maintaining optical cavity comprises an optical delay line for matching the lengths of the first polarization-maintaining optical cavity and the second polarization-maintaining optical cavity. Optionally, the optical delay line comprises a fiber-pigtailed optical delay line. The use of delay line in one or more of the optical cavities allows the pairing of non-identical optical cavities by equalizing their lengths.

Passive synchronization of multiple mode-locked fiber oscillators addresses many technical challenges, including precise timing distribution between different wavelength regions and multi-wavelength synchronized mode-locked laser sources for microscopy. A key advantage of the passive XPM based, shared common-branch synchronization mechanism is the modularity, which enables the scale up to multiple optical cavities by adding new common branches shared with adjacent cavities.

In a fourth embodiment, the optical circuit may further comprises a third polarization-maintaining optical cavity. The third polarization-maintaining optical cavity comprising: a third gain medium excitable by a third pump light source to generate light at a third range of wavelengths; and a third saturable absorber configured to carry out passive mode locking of the light pulses in the third polarization-maintaining optical cavity. In such embodiments, the second polarization-maintaining optical cavity and the third polarization-maintaining optical cavity may share a common branch, wherein the common branch does not include a saturable absorber.

The modularity of the disclosed optical circuit facilitates the transfer synchronization from the first and second optical cavities to a third optical cavity adjacent to the second optical cavity through XPM. This geometry enables adoption of the lowest accessible order XPM (3rd order non linearity) thanks to the two pulse interaction in the common branches, ensuring the strongest synchronization effect. The resulting synchronization range of the neighboring optical cavities remains unaffected by the presence of the other neighboring optical cavities.

Synchronising multiple oscillators together provides advantages in broadband coherent Raman microscopy by enabling the generation of multiple pump/Stokes couples at the same time covering multiple Raman regions all at once. One implementation for broadband SRS microscopy may use the combination of two narrowband pump/Stokes beams coupled to a broadband Stokes/pump beam: one pump/Stokes will be probing one Raman active region (i.e. CH stretching) through the broadband Stokes/pump and the other pump/Stokes, centred at a different wavelength probing another Raman active region (i.e. fingerprint) through the same broadband Stokes/pump.

Generating multiple pump/Stokes couples directly from the oscillators, enable each optical cavity to be optimized for the desired wavelength range independent of other optical cavities in the optical circuit. Additionally, the proposed solution may provide increased power spectral density at the detector for broadband SRS, leading to a higher signal-to-noise ratio at constant total average power at the detector and Raman spectral coverage. Furthermore, the proposed solution may enable improved handling of non-ultra-broadband pulses inside microscopes since the use of multiple narrowband pump/Stokes beams requires a less broad Stokes/pump pulse, thus experiencing less dispersion.

Optionally, the first range of wavelengths and the second range of wavelengths may be non-overlapping, and wherein the second range of wavelengths and the third range of wavelengths are non-overlapping.

Optionally, the first gain medium comprises a Erbium doped fiber, the second gain medium comprises a Ytterbium doped fiber, and the third gain medium comprises a Neodymium doped fiber.

Optionally, the first gain medium comprises a Erbium doped fiber, the second gain medium comprises a Ytterbium doped fiber, and the third gain medium comprises a Thulium doped fiber.

Optionally, each common branch in the optical circuit is enclosed between two wavelength division multiplexers. In some examples, each common branch in the optical circuit is enclosed between two micro-optic filter couplers or micro-optic filter splitters.

In one embodiment, each of the first polarization-maintaining optical cavity, the second polarization-maintaining optical cavity, and the third polarization-maintaining optical cavity have a ring configuration.

In one embodiment, the first polarization-maintaining optical cavity and the second polarization-maintaining optical cavity have a ring configuration, and wherein the third polarization-maintaining optical cavity has a linear configuration.

In one embodiment, the first polarization-maintaining optical cavity and the third polarization-maintaining optical cavity have a linear configuration, and wherein the second polarization-maintaining optical cavity has a ring configuration.

In an alternative embodiment, the optical circuit may further comprises a third polarization-maintaining optical cavity. The third polarization-maintaining optical cavity comprising: a third gain medium excitable by a third pump light source to generate light at a third range of wavelengths; and a third saturable absorber configured to carry out passive mode locking of the light pulses in the third polarization-maintaining optical cavity. The first polarization-maintaining optical cavity, the second polarization-maintaining optical cavity and the third polarization-maintaining optical cavity may share the same common branch, wherein the common branch does not include a saturable absorber.

In a second aspect, the disclosure provides a laser device for outputting filtered light pulses for inducing coherent Raman scattering (CRS) in a sample, the laser device may comprise any of the optical circuit arrangements according to the first aspect described above. The laser device may also comprise a first optical filter and a second optical filter, wherein the first optical filter and the second optical filter are configured to filter the light from the first polarization-maintaining optical cavity and the second optical polarization-maintaining optical cavity respectively in order to output first filtered light pulses at a first predetermined range of wavelengths and second filtered light pulses at a second predetermined range of wavelengths.

The disclosed laser device enables CRS at fast enough speeds for non-invasive imaging. That is to say, to obtain objective and quantitative information of a tissue, by measuring its detailed molecular composition through its vibrational response detected by CRS. Examples of the laser device also provide a convenient tool for pump-probe experiments, and provide a suitable pump source for parametric mixing and frequency up/down conversion.

Broadly, in the laser device described, each optical cavity of the laser device may comprise a gain element and single-mode polarization maintaining fibers. The optical cavity lengths may be matched using a fiber-pigtailed optical delay line inserted in one half. Following the synchronized oscillators, fiber amplifiers may be provided to increase the average power of the two branches to hundreds of mW level required for the application. In other words, two independent laser media are mode-locked and synchronised to provide pump and Stokes pulses for CRS. Two independent mode-locked optical cavities are locked in synchronism (i.e. pulses have the same repetition rate and constant optical delay between the two optical pulse trains) through the shared XPM interactions via a common branch between the two optical cavities. Frequency detuning is achieved either in the broadband configuration by employing a narrowband (broadband) pump and a broadband (narrowband) Stokes or in narrowband configuration by a tunable filter stage located either within or outside the cavities.

In contrast to the known implementation of CRS, where one of the two required independent pulses of different frequencies is generated through parametric amplification, in the laser device described herein, different laser media emitting at different frequencies are passively synchronized, thus greatly simplifying the generation of broadband or multi-colour (multi-frequency) pulse sequences required for CRS.

In the examples described, two independent mode-locked oscillators or optical cavities are provided that are synchronized through XPM interactions in a shared cavity segment.

The laser device described herein passively synchronizes fiber lasers, providing a very simple and low cost laser source for CRS. Fiber lasers enable robust and stable sources, owing to their simple, compact, and cost-effective designs, and an alignment-free operation that does not require bulky optical setups.

As explained below, examples of the laser device described herein, have been applied to Coherent anti-Stokes Raman Scattering (CARS) and Stimulated Raman Scattering (SRS), thus proving the concept. Due to their compactness and all-optical synchronization, the examples described are a good source for CRS in the high-wavenumber region and also in the fingerprint region.

Arrangements are described in more detail below and take the form of a laser device for outputting filtered light pulses for inducing coherent Raman scattering in a sample.

Optionally, both of the first optical filter and second optical filter may comprise fiber Bragg grating (FBG) configured to output light pulses at a first predetermined range of wavelengths and at a second predetermined range of wavelengths. A fiber Bragg grating is a short segment of fiber that reflects particular wavelengths of light and transmits all the others. This effect is obtained by creating a periodic variation in the refractive index of the fiber core, which generates a wavelength-selective mirror. FBGs can be as well designed as chirped mirrors, thus introducing a predetermined dispersion on the reflected wavelengths of light.

Optionally, both of the first optical filter and the second optical filter may comprise a fixed wavelength optical filter configured to set the first predetermined range of wavelengths and the second predetermined range of wavelengths respectively.

Optionally, both of the first optical filter and second optical filter may comprise a tunable optical filter and configured to vary the first predetermined range of wavelengths and the second predetermined range of wavelengths respectively. Tunable optical filters allow the ranges of wavelengths to be specified by the user so that the range of wavelengths of the pump and Stokes light pulses can be varied with respect to the sample being measured.

Optionally, the tunable or fixed wavelength optical filter may comprises an etalon based fiber optic tunable or fixed wavelength filter. An etalon is a dielectric material where its specific thickness and refraction index dictates the bandwidth of each transmission peak, and only one wavelength is transmitted with maximum transmission. An etalon based fiber optic tunable or fixed wavelength filter works by selecting the refraction index of the medium of the material to select a specific resonant wavelength. The wavelength in resonance with the optical length of the cavity is transmitted, whereas the other wavelengths are reflected.

Optionally, the first optical filter and the second optical filter are positioned within the first polarization-maintaining optical cavity and second polarization-maintaining optical cavity respectively, and wherein the first polarization-maintaining optical cavity and the second polarization-maintaining optical cavity respectively outputs the filtered light pulse at a first optical outlet and a second optical outlet. Having the optical filters fitted inside the optical cavities ensures light pluses with undesired ranges of wavelengths are promptly filtered after their generation.

Optionally, the first optical filter and the second optical filter are positioned externally to the first polarization-maintaining optical cavity and second polarization-maintaining optical cavity respectively, and wherein the first polarization-maintaining optical cavity and the second polarization-maintaining optical cavity respectively output the light pulses at a first optical outlet and a second optical outlet. Having the optical filters placed externally to the optical cavities eliminates the need to filter the recirculating filtered light pulses repeatedly, as well as permitting the construction of simple and compact optical cavities.

The light pulses may be filtered such that only light pulses within a defined range of wavelengths are output to coherent Raman spectroscopy, which yields a more accurate measurement. Furthermore, the use of two synchronized and mode-locked laser sources greatly reduces the impact of optical filters on the optical power of pump and Stokes pulses, making it a versatile choice for CRS.

Optionally, the laser device further comprises a first fiber amplifier doped with the first gain medium at the first optical outlet and a second fiber amplifier doped with the second gain medium at the second optical outlet for amplifying the light pulses or the filtered light pulses. This ensures the amplified light pulses are amplified in the correct wavelength range. The use of amplifiers mitigates the reduction in optical power when optical filters are in place.

Optionally, the laser device further comprises a second harmonic generation crystal operably coupled to an optical outlet of at least one of the first fiber amplifier or the second fiber amplifier. The second harmonic generation crystal may be formed from one or more of periodically poled lithium niobate PPLN or periodically poled potassium titanyl phosphate PPKTP.

Optionally, the laser device further comprises an acousto-optic modulator or an electro-optic modulator which is operably coupled to at least one of the first amplifier or the second amplifier.

Optionally, the laser device further comprises an acousto-optic modulator or an electro-optic modulator which is operably coupled to the outlet of at least one of the first polarization-maintaining optical cavity or the second polarization-maintaining optical cavity. Optionally, the spectrum of both the light pulses exiting the first polarization maintaining cavity or the second polarization maintaining cavity can be broadened in the fiber amplifier section due to self-phase modulation in order to increase the spectral bandwidth and reduce the compressed pulse duration.

Optionally, the laser device is a fiber laser. Optionally, the laser device is an all-fiber laser. Optionally, the first optical cavity and second optical cavity comprises an isotropic optical fiber. Optionally, each of the first optical cavity and second optical cavity comprises a single-mode optical fiber.

Optionally, the laser gain media comprises ytterbium or erbium, where optionally the predetermined range of wavelengths generated by said laser gain media corresponds to full Raman spectrum of 0-4000 cm⁻¹.

Optionally, the predetermined range of wavelengths comprises the range of 1000 nm to 1100 nm and/or 1535 nm to 1600 nm and/or 910 nm to 950 nm and/or 1800 nm to 1900 nm.

Optionally, frequency conversion of the amplified light pulses can be implemented using second-harmonic generation crystals (i.e. periodically poled lithium niobate-PPLN-, periodically poled potassium titanyl phosphate-PPKTP-).

Optionally, an acousto-optic modulator (AOM) or an electro-optic modulator (EOM) can be placed outside of both the first polarization maintaining cavity and the second polarization-maintaining cavity.

In a third aspect, the disclosure provides an optical device. The optical device may comprise any of the laser devices described above. Additionally, the optical device comprises two collimators configured to collimate the filtered light pulses. This limits the divergence of filtered light pulses. Optionally, one of the collimators comprises a delay stage configured to achieve an overlap on the measured sample.

Optionally, the optical device further comprises a dichroic mirror configured to combine the collimated light pulses from both of the two collimators.

Optionally, the laser device comprises a bandpass or shortpass filter for removing the pair of filtered light pulses prior to CARS detection.

Optionally, the laser device comprises a bandpass or longpass filter for removing the pump light pulses prior to SRG detection.

Optionally, the laser device comprises a bandpass or shortpass filter for removing the Stokes light pulses prior to SRL detection.

In a fourth aspect, the disclosure provides a method of outputting filtered light pulses from a laser device for inducing coherent Raman scattering in a sample. The method comprises generating light at respective different ranges of wavelengths with a first polarization-maintaining optical cavity comprising a first gain medium and a second polarization-maintaining optical cavity comprising a second gain medium different to the first gain medium, wherein the first gain medium and the second gain medium are each excitable by a pump light source. Mode-locking is performed via a first and second saturable absorber optically coupled to the first polarization-maintaining optical cavity and the second polarization-maintaining optical cavity respectively. The method further comprising synchronising, via a common branch between the first polarization-maintaining optical cavity and the second polarization-maintaining optical cavity, the light from the first polarization-maintaining optical cavity and the second polarization-maintaining optical cavity, wherein the common branch does not include a saturable absorber.

In a fifth aspect, the disclosure provides an optical circuit for a laser device. The optical circuit comprising N polarization-maintaining optical cavities. Each of the N polarization-maintaining optical cavities comprising: a gain medium excitable by a pump light source to generate light at a range of wavelengths; and a saturable configured to carry out passive mode locking of the light pulses in the polarization-maintaining optical cavity. Each of the N polarization-maintaining optical cavities share a common branch with at least one other polarization-maintaining optical cavity of the N polarization-maintaining optical cavities. Wherein the common branches between the N polarization-maintaining optical cavities do not comprise a saturable absorber.

Optionally, the gain medium of each polarization-maintaining optical cavity is excitable by a pump light source to generate light at a range wavelengths which does not overlap with a range of wavelengths of light generated by exciting the gain medium of adjacent polarization-maintaining optical cavities.

Optionally, at least N-1 of the polarization-maintaining optical cavities comprise an optical delay line for matching the length of the cavities for synchronization purposes.

Optionally, the optical delay line comprises a fiber-pigtailed optical delay line.

Optionally, each of the N polarization-maintaining optical cavities have a ring configuration.

Optionally, 1≤M≤2 cavities of the N polarization-maintaining optical cavities have a linear configuration and N-M cavities of the N polarization-maintaining optical cavities have a ring configuration.

It will be appreciated that the features described in relation to the first, second, third and fourth aspects of the disclosure may also be applied to the fifth aspect.

### BRIEF DESCRIPTION OF THE DRAWINGS

The invention will be described in more detail, by way of example, with reference to the accompanying drawings, in which:

FIG. 1 is a schematic of an optical circuit according to a first embodiment of the present invention;

FIG. 2 is a schematic of an optical circuit according to a second embodiment of the present invention;

FIG. 3 is a schematic of an optical circuit according to a third embodiment of the present invention; and

FIG. 4 is a schematic of an optical device according to the present invention;

FIG. 5 is a schematic of an optical circuit according to an embodiment of the present invention;

FIG. 6 is a schematic of an optical circuit according to an embodiment of the present invention;

FIG. 7 is a schematic of an optical circuit according to an embodiment of the present invention.

### DETAILED DESCRIPTION OF THE INVENTION

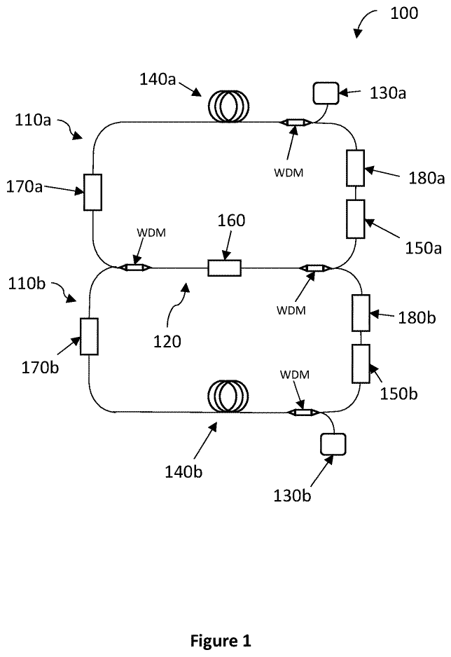

Optical circuits for use in laser devices for inducing coherent Raman scattering in a sample according to examples of the present invention are described below with reference to FIGS. 1 to 3 and 5 to 7.

FIG. 1 illustrates an optical circuit 100 according to a first embodiment of the present invention. Optical circuit 100 comprises two independent mode-locked optical cavities, oscillators or resonators for generating two sets of light pulses at order of picosecond durations at different ranges of wavelengths suitable for CRS. The two optical cavities 110a, 110b are joined together at a common branch 120.

In more detail, continuing to refer to optical circuit 100 of FIG. 1, each of the two optical cavities 110a, 110b of optical circuit 100 of FIG. 1 are arranged in the form of a loop. The ends of optical fibres making up optical cavities 110a, 110b are optically connected using any suitable couplers, in order to circulate the light pulses in the loops until their discharge from the optical cavities at their respective optical outlets. Furthermore, each of the optical outlets comprises fibre couplers to provide approximately 20-30% output for their respective cavities. The mode-locked optical cavities 110a, 110b each include a pump light source 130a, 130b to each of the optical cavities 110a, 110b to excite gain elements 140a, 140b that are located or deposited inside the optical cavities 110a, 110b. The gain elements 140a, 140b, in this example, are optical fibres doped with rare earth gain elements. Laser devices using such gain elements are commonly referred to as fiber lasers.

The choice of pump light sources 130a, 130b and the gain elements 140a, 140b depend on the light spectra required by the CRS. The example shown in FIG. 1 uses two different optical fibers as the gain elements. One optical fiber is doped with a rare earth gain element in the form of ytterbium (Yb) 140a. The other optical fiber is doped with a rare earth gain element in the form of erbium (Er) 140b. In this example, the pump light sources to excite the gain elements are a 976 nm wavelength pump light source 130a to excite the Yb doped fiber; and a 976 nm wavelength pump light source 130b to excite the Er doped fiber. The light pulses generated from the Yb and Er gain media are in the range of desirable pump and Stokes wavelengths.

An optical isolator 150a, 150b is optically coupled in each of the optical cavities 110a, 110b in order to force the same direction of circulation inside the common branch 120. This ensures that the light pulses generated by the gain media 140a, 140b in the optical cavities travel in a single direction in the loops forming the optical cavities 110a, 110b. That is, light pulses generated from the gain media 140a, 140b are directed towards the optical outlets. In this example, the optical isolators 150a, 150b are fiber based Faraday isolators. In other examples, optical isolators 150a, 150b may comprise polarizing circulators with dispersion compensating devices and output couplers.

The pair of light pulses generated in each of the optical cavities 110a, 110b are passively synchronized via XPM interactions in common branch 120, shared by both loops forming the optical cavities 110a, 110b. In this example, common branch 120 comprises a high non-linearity device or material 160 to enhance XPM interaction strength for synchronization.

Optical cavities 110a, 110b each comprise their own saturable absorber 170a, 170b outside of common branch 120. The function of a saturable absorber is described in the summary of invention section above. A saturable absorber is a light absorber whose degree of absorption is reduced at high optical intensities. In optical circuit 100, this allows passive mode-locked pulses to circulate in each of optical cavities 110a, 110b. That is, passive mode-locking allows the generation of femtosecond light pulses. Saturable absorber 170a, 170b possesses a sufficiently short recovery time so that fast loss modulation is achieved. The saturable absorber 170a, 170b in FIG. 1 may be a graphene based polymer-composite saturable absorber, which has ultrafast recovery time and broadband operation. A graphene saturable absorber may be prepared by exfoliating bulk graphite by mild ultrasonication, wherein a dispersion first enriched with obtained single layer graphene and few layer graphene is mixed with an aqueous solution of polyvinyl alcohol, resulting in a polymer composite. Other saturable absorbers may alternatively be used for carrying out passive mode locking of the light pulses, for example saturable absorbers comprising single-wall carbon nanotubes (CNT), however any of the saturable absorbers described in the summary of invention section above may be utilized.

The pair of optical cavities 110a, 110b do not need to be identical. The difference in cavity lengths between the two optical cavities 110a, 110b is compensated for by the addition of an optical delay line 180a, 180b to either one or both of the optical cavities. In this example, an optical delay line 180a, 180b is located in both optical cavities 110a, 110b after isolator 150a, before isolator 150b. In this example, optical delay line 180a, 180b comprises a fiber-pigtail delay line. The fiber-pigtail delay line is optically coupled to the outlet of the isolator 150a, to the inlet of 150b in each optical cavities 110a, 110b. In other examples, the optical delay line 180a, 180b may comprise an output coupler in series.

The ranges of wavelengths of the light pulses generated at each of the optical cavities 110a, 110b are dictated by the type of gain media being excited in the respective optical cavity.

Each of the optical cavities 110a, 110b have an outlet to together output first filtered light pulses at a first predetermined range of wavelengths and second filtered light pulses at a second predetermined range of wavelengths from the optical circuit 100. In an example, the outlets may be located in 150a, 150b if they are circulators with dispersion compensating device and output couplers. The optical outlets may each be coupled to a different fiber amplifier. The relevant fiber amplifier may be doped with a gain element corresponding to the gain medium 140a, 140b that is responsible for light pulse generation. In an example, Yb- and Er-doped fibre amplifiers are respectively provided for optical cavities 110a, 110b, in order to amplify the light pulses at the Yb and Er wavelengths to 100 mW average power.

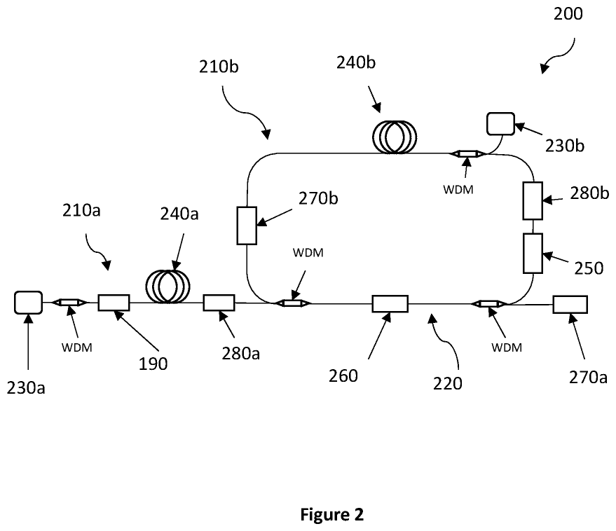

FIG. 2 illustrates an optical circuit 200 according to a second embodiment of the present invention. Similarly to the optical circuit 100 shown in FIG. 1, optical circuit 200 comprises two independent mode-locked optical cavities, oscillators or resonators for generating two sets of light pulses at order of picosecond durations at different ranges of wavelengths suitable for CRS. The two optical cavities 210a, 210b are joined together at a common branch 220.

Unlike optical circuit 100, in optical circuit 200, only one of the two optical cavities 210b of optical circuit 200 is arranged in the form of a loop, while the other optical cavity 210a is arranged in a linear configuration. As in optical circuit 100, the mode-locked optical cavities 210a, 210b of optical circuit 200 each include a pump light source 230a, 230b to each of the optical cavities 210a, 210b to excite gain elements 240a, 240b that are located or deposited inside the optical cavities 210a, 210b. The gain elements 240a, 240b, in this example, are optical fibres doped with rare earth gain elements.

An optical isolator 250 is optically coupled within optical cavity 210b. This is in order to ensure that the light pulses generated by the gain media 240b travel in a single or in one and only one direction in the loop forming optical cavity 210b. That is, light pulses generated from the gain media 240b are directed towards the optical outlet. In this example, the optical isolator 250 may include a fiber based Faraday isolator. In other examples, optical isolator 250 may comprise polarizing circulators with dispersion compensating devices and output couplers.

As described in relation to optical circuit 100, the pair of light pulses generated in each of the optical cavities 210a, 210b are passively synchronized via XPM interactions in common branch 220, shared by both optical cavities 210a, 210b. In this example, common branch 220 comprises a high non-linearity device or material 260 to enhance XPM interaction strength for synchronization.

Optical cavities 210a, 210b each comprise their own saturable absorber 270a, 270b outside of common branch 220. As described in relation to optical circuit 100, in optical circuit 200, this allows passive mode-locked pulses to circulate in each of optical cavities 210a, 210b. Saturable absorber 270a, 270b possesses a sufficiently short recovery time so that fast loss modulation is achieved. Any of the saturable absorbers mentioned in this disclosure may be utilised in optical circuit 200. Where a transmissive saturable absorber is provided in a linear optical cavity, a fiber-coupled mirror must be provided within the optical cavity after the saturable absorber.

The difference in cavity lengths between the two optical cavities 210a, 210b is compensated for by the addition of an optical delay line 280a, 280b to either one of the optical cavities. In this example, an optical delay line 280a, is located in optical cavity 210a after gain medium 240a, while optical delay line 280b, is located in optical cavity 210b after isolator 250. In this example, optical delay lines 280a, 280b comprises a fiber-pigtail delay line. The fiber-pigtail delay line is optically coupled to the outlet of the isolator 250 in optical cavity 210b. In other examples, the optical delay line 280a, 280b may comprise an output coupler in series.

Optical cavity 210a has a dispersion compensator and output coupler (chirped fiber Bragg grating in this example) 190 to output first filtered light pulses at a first predetermined range of wavelengths from optical circuit 200. Optical cavity 210b has a corresponding outlet to output second filtered light pulses at a second predetermined range of wavelengths from the optical circuit 200. In an example, the outlets may be located in 190 and in 280b. The optical outlets may each be coupled to a different fiber amplifier. The relevant fiber amplifier may be doped with a gain element corresponding to the gain medium 240a, 240b that is responsible for light pulse generation. In an example, Yb- and Er-doped fibre amplifiers are respectively provided for optical cavities 210a, 210b, in order to amplify the light pulses at the Yb and Er wavelengths to 100 mW average power.

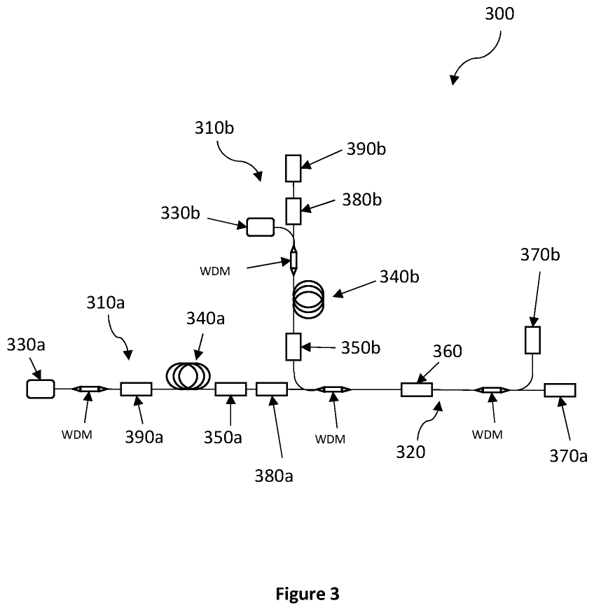

FIG. 3 illustrates an optical circuit 300 according to a third embodiment of the present invention. Similarly to optical circuits 100 and 200, optical circuit 300 comprises two independent mode-locked optical cavities, oscillators or resonators for generating two sets of light pulses at order of picosecond durations at different ranges of wavelengths suitable for CRS. The two optical cavities 310a, 310b are joined together at a common branch 320.

Unlike optical circuits 100 and 200, in optical circuit 300, both of the two optical cavities 310a, 310b of optical circuit 300 are arranged in a linear configuration. As in optical circuits 100 and 200, the mode-locked optical cavities 310a, 310b of optical circuit 300 each include a pump light source 330a, 330b to each of the optical cavities 310a, 310b to excite gain elements 340a, 340b that are located or deposited inside the optical cavities 310a, 310b. The gain elements 340a, 340b, in this example, are optical fibres doped with rare earth gain elements.

Optical circuit 300 may comprise a polarizing coupler 350a, 350b optically coupled to the outlet of gain medium 340a, 340b in optical cavity 310a, 310b respectively. This is used to select the polarization state on the slow axis and can act as the optical outlet.

As described in relation to optical circuits 100 and 200, the pair of light pulses generated in each of the optical cavities 310a, 310b are passively synchronized via XPM interactions in common branch 320, shared by both optical cavities 310a, 310b. In this example, common branch 320 comprises a high non-linearity device or material 360 to enhance XPM interaction strength for synchronization. In this linear-linear optical cavity arrangement, the effective XPM interaction length is increased since each generated light pulse in each optical cavity 310a, 310b passes common branch 320 twice. This improves the permissible cavity mismatch in the optical circuit 300.

Optical cavities 310a, 310b each comprise their own saturable absorber 370a, 370b outside of common branch 320. As described in relation to optical circuits 100 and 200, in optical circuit 300, this allows passive mode-locked pulses to circulate in each of optical cavities 310a, 310b. Saturable absorber 370a, 370b possesses a sufficiently short recovery time so that fast loss modulation is achieved. Any of the saturable absorbers mentioned in this disclosure may be utilised in optical circuit 300.

The difference in cavity lengths between the two optical cavities 310a, 310b is compensated for by the addition of an optical delay line 380a, 380b to either one of the optical cavities. In this example, an optical delay line 380a, is located in optical cavity 310a after gain medium 340a, while optical delay line 380b, is located in optical cavity 310b after gain medium 340b. In this example, optical delay lines 380a, 380b may comprise a fiber-pigtail delay line.

Optical cavities 310a, 310b have dispersion compensators and output couplers 390a, 390b to output first filtered light pulses at a first predetermined range of wavelengths and second filtered light pulses at a second predetermined range of wavelengths from the optical circuit 300 (chirped fiber Bragg grating in this example). The optical outlets may each be coupled to a different fiber amplifier. The relevant fiber amplifier may be doped with a gain element corresponding to the gain medium 340a, 340b that is responsible for light pulse generation. In an example, Yb- and Er-doped fibre amplifiers are respectively provided for optical cavities 310a, 310b, in order to amplify the light pulses at the Yb and Er wavelengths to 100 mW average power.

In other embodiments, dispersion compensators and output couplers 390a, 390b may be replaced with high reflectivity mirrors while polarizing couplers 350a, 350b are used as the output couplers.

In each of the disclosed optical circuits 100, 200 and 300, the position of the SAs and/or the common branch with respect to components within the circuit may vary, providing the common branch 320 and dedicated WDMs are positioned within each cavity after the pump diodes 330a, 330b and the active fiber-gain elements 340a, 340b. The SAs can be positioned either before or after the common branch.

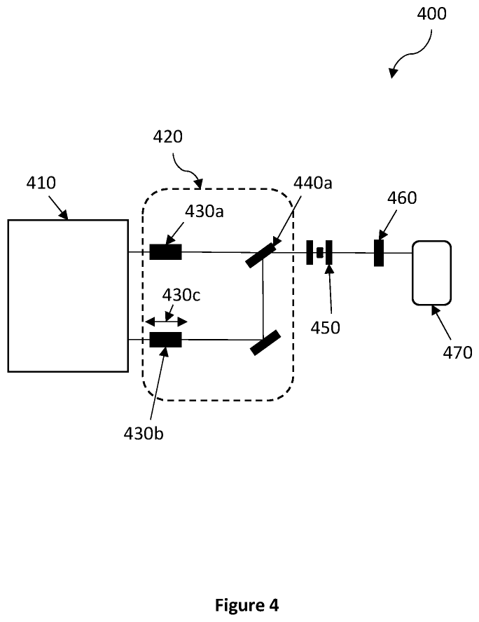

FIG. 4 illustrates an optical device 400 according to the present invention. Optical device 400 comprises an optical circuit 410 along with further optical elements 420. Optical circuit 410 may comprise any of optical circuits 100, 200 or 300 described above. Optical elements 420 direct the light pulses generated by optical circuit 410 to illuminate a sample 450 on which coherent Raman scattering is being carried out. The scattering from the sample is filtered by a shortpass, bandpass or longpass filter 460 before entering a multichannel dispersive detector 470 (i.e. spectrometer, multi-channel lock-in amplifier).

The optical elements 420 of the arrangement or setup illustrated in FIG. 4 includes collimators 430a, 430b. The optical circuit 410 outputs two filtered light pulses each through a collimator. Thus, the two filtered light pulses are collimated in their respective collimators 430a, 430b, in order to limit the divergence of the beams of light pulses when they are combined in a subsequent combination step by dichroic mirror 440a. In some cases, where it is necessary to achieve an overlap on a sample 450, one of the two collimators 430a, 430b may be placed on a delay stage 430c. Alternatively or additional, a delay stage 430c may be provided before the collimators 430a, 430b.

The optical elements 420 of the arrangement or setup illustrated in FIG. 4 also includes a dichroic mirror 440a. A dichroic mirror is a mirror with different reflection and transmission properties at different wavelengths. The two collimated light pulses from the different cavities are combined using the dichroic mirror 440a. They are then focused into the sample 450. A shortpass or bandpass or longpass filter 460 and then a multichannel dispersive detector 470 are located downstream of the sample. In CARS detection configuration, the pump and Stokes light pulses from the sample are removed using the shortpass filter 460. A shortpass filter is a filter with a very sharp transition from transmission to reflection. The resulting CARS spectrum is measured at the spectrometer 470. In SRS configuration (either SRG or SRL), the pump (SRG) or Stokes (SRL) light pulses are removed after the sample with a longpass (SRG) or shortpass (SRL) optical filter 460. The resulting SRG or SRL spectrum is measured at the multichannel lock-in amplifier 470.

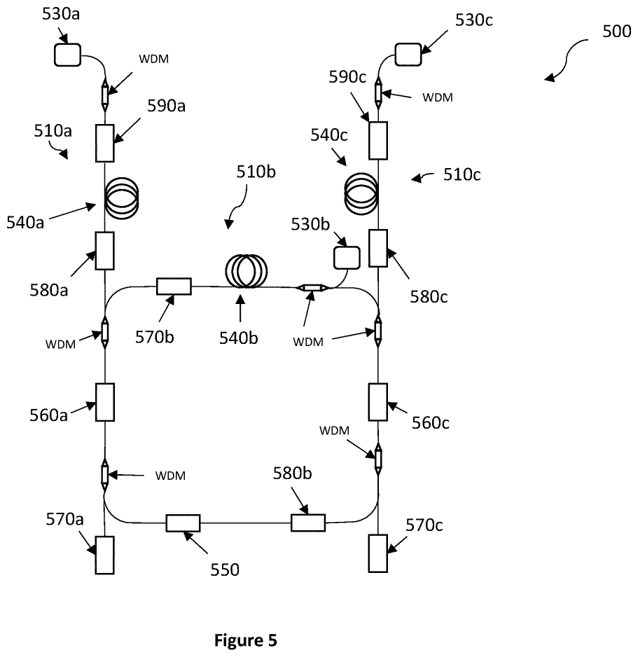

FIG. 5 illustrates an optical circuit 500 according to an embodiment of the present invention comprising three optical cavities 510a, 510b, 510c, each comprising a pump light source 530a, 530b, 530c to each of the optical cavities 510a, 510b, 510c to excite gain elements 540a, 540b, 540c that are located or deposited inside the optical cavities 510a, 510b, 510c. The gain elements 540a, 540b, 540c in this example, are optical fibres doped with rare earth gain elements.

The first optical cavity 510a shares a common branch with the second optical cavity 510b in a manner equivalent to that in optical circuit 200 of FIG. 2. Unlike optical circuit 200, second optical cavity 510b of optical circuit 500 comprises a second common branch shared with a third optical cavity 510c.

An optical isolator 550 is optically coupled within optical cavity 510b. This is in order to ensure that the light pulses generated by the gain media 540b travel in a single or in one and only one direction in the loop forming optical cavity 510b. That is, light pulses generated from the gain media 540b are directed towards the optical outlet. In this example, the optical isolator 550 may include a fiber based Faraday isolator. In other examples, optical isolator 550 may comprise polarizing circulators with dispersion compensating devices and output couplers.

Light pulses generated in each of the optical cavities 510a, 510b, 510c are passively synchronized via XPM interactions in common branches, shared between optical cavities 510a-510b, and 510b-510c. In this example, the common branches comprises a high non-linearity device or material 560a, 560c to enhance XPM interaction strength for synchronization.

Optical cavities 510a, 510b, 510c each comprise their own saturable absorber 570a, 570b, 570c outside of the common branches. As described above, this allows passive mode-locked pulses to circulate in each of optical cavities 510a, 510b, 510c. Saturated absorber 570a, 570b, 570c possesses a sufficiently short recovery time so that fast loss modulation is achieved. Any of the saturable absorbers mentioned in this disclosure may be utilised in optical circuit 500.

The difference in cavity lengths between the optical cavities 510a-510b and between optical cavities 510b-510c is compensated for by the addition of optical delay lines 580a, 580b, 580b in one or more of the optical cavities. In this example, optical delay lines 580a and 580c are located in optical cavities 510a and 510c after gain mediums 540a and 540c respectively, while optical delay line 580b, is located in optical cavity 510b after isolator 550. In this example, optical delay lines 580a, 580b, 580c comprises a fiber-pigtail delay line. The fiber-pigtail delay line is optically coupled to the outlet of the isolator 550 in optical cavity 510b. In other examples, the optical delay line 580a, 580b, 580c may comprise an output coupler in series.

Optical cavities 510a and 510c have dispersion compensators and output coupler (chirped fiber Bragg grating in this example) 590a, 590c to output first filtered light pulses at a first predetermined range of wavelengths from optical circuit 500. Optical cavity 510b has a corresponding outlet to output second filtered light pulses at a second predetermined range of wavelengths from the optical circuit 500. In an example, the outlets may be located in 590a, 590c and in 580b. The optical outlets may each be coupled to a different fiber amplifier. The relevant fiber amplifier may be doped with a gain element corresponding to the gain medium 540a, 540b, 540c that is responsible for light pulse generation. In an example, Er-, Yb- and Nd-doped fibre amplifiers are respectively provided for optical cavities 510a, 510b, 510c in order to amplify the light pulses at the Er, Yb and Nd wavelengths to 100 mW average power.

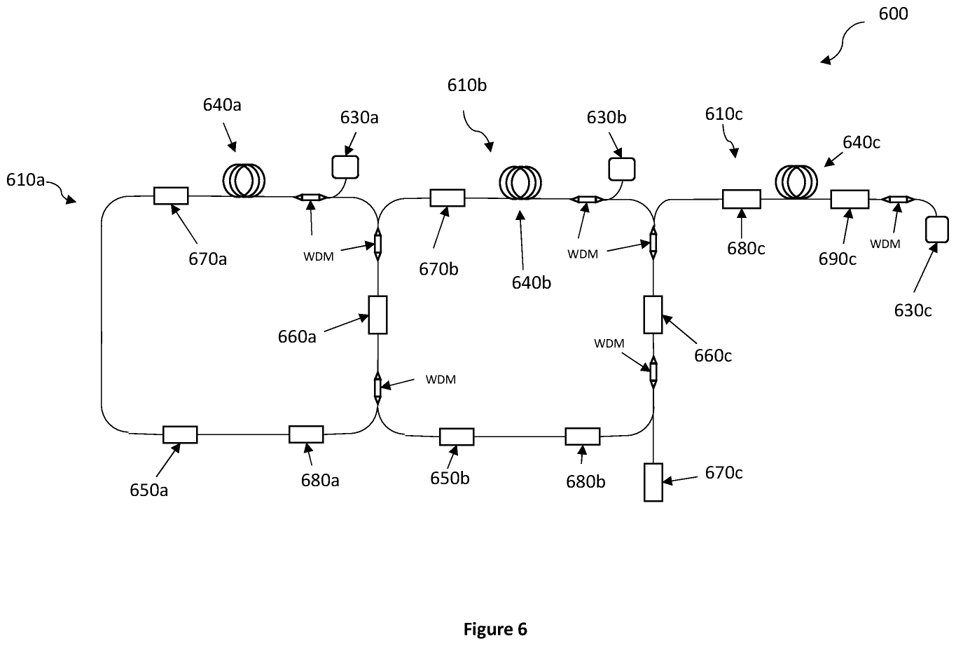

FIG. 5 illustrates an optical circuit 500 having three optical cavities 510a, 510b, 510c arranged in a linear-ring-linear configuration. However it will be appreciated that alternative arrangements are also possible. For example, FIG. 6 illustrates a similar optical circuit 600 to that shown in FIG. 5, and has three optical cavities 610a, 610b, 610c. In optical circuit 600, however, optical cavity 610a is in a ring configuration, thereby forming a ring-ring-linear configuration optical circuit 600. Despite the differences in configuration, optical circuit 600 may function in a similar manner to optical circuit 500.

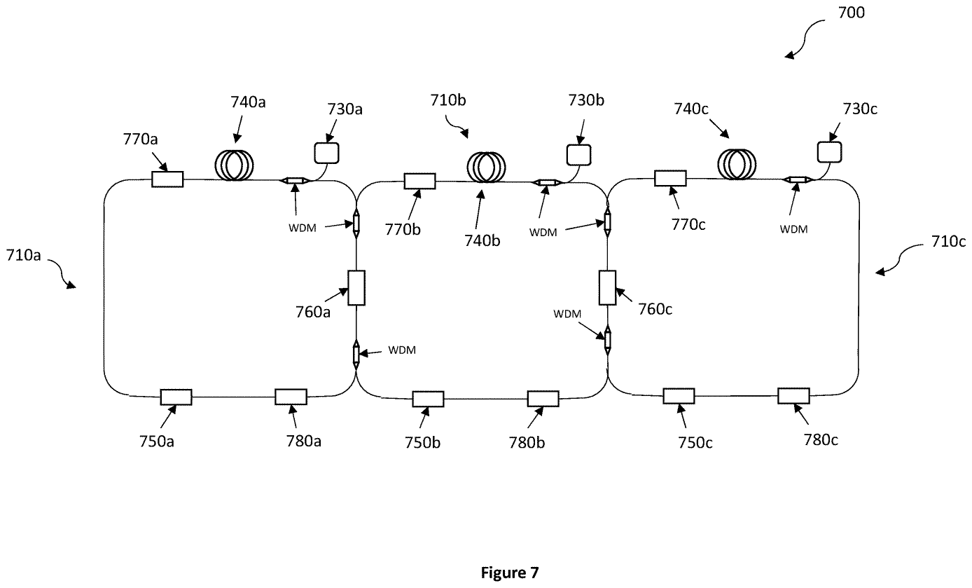

FIG. 7 illustrates having three optical cavities 710a, 710b, 710c arranged in a ring-ring-ring configuration. As discussed in relation to optical circuit 600, the features described with respect to optical circuit 500 apply equally to optical circuit 700.

It will be appreciated that although not illustrated, optical circuits in accordance with the present invention may comprise more than three optical cavities and in a variety of configurations. In one example, the optical circuit comprising N optical cavities, each optical cavity sharing a common branch with at least one adjacent optical cavity. In some examples, all N optical cavities may be arranged in a ring/loop configuration. In other examples, 1<M<2 optical cavities of the N optical cavities may be arranged in a linear configuration, while N-M optical cavities are arranged in a ring/loop configuration.

Embodiments of the present invention have been described. It will be appreciated that variations and modifications may be made to the described embodiments within the scope of the present invention.

1. An optical circuit for a laser device, the optical circuit comprising:
a first polarization-maintaining optical cavity comprising:
a first gain medium excitable by a first pump light source to generate light at a first range of wavelengths; and
a first saturable absorber configured to carry out passive mode locking of the light pulses in the first polarization-maintaining optical cavity; and
a second polarization-maintaining optical cavity comprising:
a second gain medium different to the first gain medium excitable by a second pump light source to generate light at a second range of wavelengths; and
a second saturable absorber configured to carry out passive mode locking of the light pulses in the second polarization-maintaining optical cavity,
wherein the first polarization-maintaining optical cavity and the second polarization-maintaining optical cavity share a common branch, and wherein the common branch does not include a saturable absorber.

2. The optical circuit according to claim 1, wherein the first polarization-maintaining optical cavity has a ring configuration and the second polarization-maintaining optical cavity has a ring configuration.

3. The optical circuit according to claim 1, wherein the first polarization-maintaining optical cavity has a linear configuration and the second polarization-maintaining optical cavity has a ring configuration.

4. The optical circuit according to claim 1, wherein the first polarization-maintaining optical cavity has a linear configuration and the second polarization-maintaining optical cavity has a linear configuration.

5. The optical circuit according to any preceding claim, wherein the first saturable absorber is a different form of saturable absorber to the second saturable absorber.

6. The optical circuit according to any preceding claim, wherein at least one of the first saturable absorber or the second saturable absorber comprises at least one of a Graphene/carbon allotrope, single-walled carbon nanotube, semiconductor saturable absorber mirror, or transmissive semiconductor based saturable absorber.

7. The optical circuit according to claim 2, wherein the first saturable absorber is a transmissive semiconductor based saturable absorber and the second saturable absorber is a transmissive semiconductor based saturable absorber.

8. The optical circuit according to claim 3, wherein the first saturable absorber is a semiconductor saturable absorber mirror and the second saturable absorber is a transmissive semiconductor based saturable absorber.

9. The optical circuit according to claim 4, wherein the first saturable absorber is a semiconductor saturable absorber mirror and the second saturable absorber is a semiconductor saturable absorber mirror.

10. The optical circuit according to any preceding claim, wherein the common branch comprises a single mode polarization-maintaining fiber or a single mode fiber.

11. The optical circuit according to any preceding claim, wherein the common branch includes a high non-linearity device or material.

12. The optical circuit according to any preceding claim, wherein at least one of the first polarization maintaining optical cavity or the second polarization-maintaining optical cavity comprises a polarizing isolator or a dispersion compensating device or a circulator with dispersion compensating device.

13. The optical circuit according to any preceding claim, wherein at least one of the first gain medium or the second gain medium comprises a ytterbium, erbium, neodymium or thulium doped fiber.

14. The optical circuit according to any preceding claim, wherein at least one of the first polarization-maintaining optical cavity or the second polarization-maintaining optical cavity comprises an optical delay line for matching the lengths of the first polarization-maintaining optical cavity and the second polarization-maintaining optical cavity, and optionally wherein the optical delay line comprises a fiber-pigtailed optical delay line.

15. The optical circuit according to any preceding claim, wherein each of the first polarization-maintaining optical cavity and second polarization-maintaining optical cavity comprises at least one of an isotropic optical fiber or a single-mode optical fiber.

16. The optical circuit according to any preceding claim, further comprising a third polarization-maintaining optical cavity comprising:
a third gain medium excitable by a third pump light source to generate light at a third range of wavelengths; and
a third saturable absorber configured to carry out passive mode locking of the light pulses in the third polarization-maintaining optical cavity,
wherein the second polarization-maintaining optical cavity and the third polarization-maintaining optical cavity share a common branch, and wherein the common branch does not include a saturable absorber.

17. The optical circuit according to claim 16, wherein the first range of wavelengths and the second range of wavelengths are non-overlapping, and wherein the second range of wavelengths and the third range of wavelengths are non-overlapping.

18. The optical circuit according to any of claims 16 or 17, wherein the first gain medium comprises a Erbium doped fiber, the second gain medium comprises a Ytterbium doped fiber, and the third gain medium comprises a Neodymium doped fiber.

19. The optical circuit according to any of claims 16 or 17, wherein the first gain medium comprises a Erbium doped fiber, the second gain medium comprises a Ytterbium doped fiber, and the third gain medium comprises a Thulium doped fiber.

20. The optical circuit according to any of claims 16 to 19, wherein each common branch in the optical circuit is enclosed between two wavelength division multiplexers.

21. The optical circuit according to any of claims 16 to 20, wherein each common branch in the optical circuit is enclosed between two micro-optic filter couplers or micro-optic filter splitters.

22. The optical circuit according to any of claims 16 to 21, wherein each of the first polarization-maintaining optical cavity, the second polarization-maintaining optical cavity, and the third polarization-maintaining optical cavity have a ring configuration.

23. The optical circuit according to any of claims 16 to 21, wherein the first polarization-maintaining optical cavity and the second polarization-maintaining optical cavity have a ring configuration, and wherein the third polarization-maintaining optical cavity has a linear configuration.

24. The optical circuit according to any of claims 16 to 21, wherein the first polarization-maintaining optical cavity and the third polarization-maintaining optical cavity have a linear configuration, and wherein the second polarization-maintaining optical cavity has a ring configuration.

25. The optical circuit according to any preceding claim, wherein the optical circuit comprises N polarization-maintaining optical cavities including the first, and second polarization-maintaining optical cavities, each of the N polarization-maintaining optical cavities sharing a common branch with an adjacent polarization-maintaining optical cavity, wherein the common branch does not include a saturable absorber.

26. The optical circuit according to claim 25, wherein the gain medium of each polarization-maintaining optical cavity is excitable by a pump light source to generate light at a range wavelengths which does not overlap with a range of wavelengths of light generated by exciting the gain medium of adjacent polarization-maintaining optical cavities.

27. The optical circuit according to any of claims 25 to 26, wherein at least N-1 of the polarization-maintaining optical cavities comprise an optical delay line for matching the length of the cavities for synchronization purposes.

28. The optical circuit according to claim 27, wherein the optical delay line comprises a fiber-pigtailed optical delay line.

29. The optical circuit according to any of claims 25 to 28, wherein each of the N polarization-maintaining optical cavities have a ring configuration.

30. The optical circuit according to any of claims 25 to 28, wherein 1≤M≤2 cavities of the N polarization-maintaining optical cavities have a linear configuration and N-M cavities of the N polarization-maintaining optical cavities have a ring configuration.

31. A laser device for outputting filtered light pulses for inducing coherent Raman scattering in a sample, the laser device comprising:
the optical circuit according to any preceding claim; and
a first optical filter and a second optical filter, wherein the first optical filter and the second optical filter are configured to filter the light from the first polarization-maintaining optical cavity and the second optical polarization-maintaining optical cavity respectively in order to output first filtered light pulses at a first predetermined range of wavelengths and second filtered light pulses at a second predetermined range of wavelengths.

32. The laser device according to claim 31 wherein at least one of the first optical filter or second optical filter is a tunable optical filter and configured to vary the first predetermined range of wavelengths or the second predetermined range of wavelengths respectively, and optionally wherein the tunable optical filter comprises an etalon based fiber optic tunable filter.

33. The laser device according to any one of claims 31-32, wherein the first optical filter and the second optical filter are positioned within the first polarization-maintaining optical cavity and second polarization-maintaining optical cavity respectively, and wherein the first polarization-maintaining optical cavity and the second polarization-maintaining optical cavity respectively outputs the filtered light pulse at a first optical outlet and a second optical outlet.

34. The laser device according to any one of claims 31 to 33, further comprising a first fiber amplifier doped with the first gain medium at the first optical outlet and a second fiber amplifier doped with the second gain medium at the second optical outlet for amplifying the light or the filtered light pulses.

35. The laser device according to claim 34, wherein a second harmonic generation crystal, an acousto-optic modulator or an electro-optic modulator is operably coupled to an optical outlet of at least one of the first fiber amplifier or the second fiber amplifier.

36. The laser device according to any one of claims 31-34, wherein an acousto-optic modulator or an electro-optic modulator is operably coupled to the outlet of at least one of the first polarization-maintaining optical cavity or the second polarization-maintaining optical cavity.

37. The laser device according to any one of claims 31-36, wherein the laser device is one of a fiber laser or an all-fiber laser.

38. The laser device according to any one of claims 31-37, wherein the predetermined range of wavelengths corresponds to a full Raman spectrum of 0-4000 cm⁻¹, and optionally wherein the predetermined range of wavelengths comprises the range of at least one of 1000 nm to 1100 nm and/or 1535 nm to 1600 nm and/or 910 nm to 950 nm and/or 780 nm to 800 nm and/or 1800 nm to 1900 nm.

39. An optical device comprising the laser device according to any one of claims 31-38, and two collimators configured to collimate the filtered light pulses, and optionally further comprising a dichroic mirror configured to combine the collimated light pulses from both of the two collimators.

40. A method of outputting filtered light pulses from a laser device for inducing coherent Raman scattering in a sample, the method comprising:
generating light at respective different ranges of wavelengths with a first polarization-maintaining optical cavity comprising a first gain medium and a second polarization-maintaining optical cavity comprising a second gain medium different to the first gain medium, wherein the first gain medium and the second gain medium are each excitable by a pump light source;
mode-locking, with a first and second saturable absorber optically coupled to the first polarization-maintaining optical cavity and the second polarization-maintaining optical cavity respectively, the light from the first polarization-maintaining optical cavity and the second polarization-maintaining optical cavity;
filtering, with a first optical filter and a second optical filter, the light from the first polarization-maintaining optical cavity and the second polarization-maintaining optical cavity respectively;
outputting from the first optical filter first filtered light pulses at a first predetermined range of wavelengths and outputting from the second optical filter second filtered light pulses at a second predetermined range of wavelengths; and
synchronising, via a common branch between the first polarization-maintaining optical cavity and the second polarization-maintaining optical cavity, the light from the first polarization-maintaining optical cavity and the second polarization-maintaining optical cavity, wherein the common branch does not include a saturable absorber.

41. The method according to claim 40, wherein the first predetermined range of wavelengths does not overlap with the second predetermined range of wavelengths.
